(19) United States
(12) Patent Application Publication
(10) Pub. No.: US 2026/0271619 A1
(43) Pub. Date: Sep. 10, 2026

(54) INTEGRATED MULTI-PHASE THERMOELECTRIC REACTOR AND ENERGY HARVESTING SYSTEM

(71) Applicant: Sophia Korman, Tallahassee, FL (US)

(72) Inventor: Sophia Korman, Tallahassee, FL (US)

(21) Appl. No.: 19/558,434

(22) Filed: Mar. 5, 2026

Related U.S. Application Data
(60) Provisional application No. 63/766,988, filed on Mar. 5, 2025.

(51) Int. Cl. H10N 10/13; H10N 10/17

(52) U.S. Cl. CPC H10N 10/13; H10N 10/17

(57) ABSTRACT

A modular, self-sustaining reactor assembly is provided for the simultaneous processing of industrial waste and the harvesting of exothermic energy. The assembly features a reaction core nested within a multi-shell architecture, configured for high-enthalpy mineralization reactions. A radial thermal manifold, characterized by a copper star geometry with flared arms, facilitates the efficient conduction of heat flux from the reaction core to a surrounding thermoelectric generator array. An atmospheric control system utilizes a dual-path nitrogen manifold to provide a first path for steady-state thermal stabilization of the thermoelectric generators and a second, high-pressure path for the scavenging and discharge of mineralized byproducts. The control architecture enables the system to transition from an externally powered startup phase to an energy-autonomous operational mode. The modular design allows for the integration of multiple assemblies into a staggered operational array for continuous, grid-scale power generation.

### CROSS-REFERENCE TO ALL RELATED APPLICATIONS

This application claims the benefit of U.S. Provisional Application No. 63/766,988, filed 5 Mar. 2025, the entire contents of which are incorporated herein by reference.

### FIELD OF THE INVENTION

The present invention relates generally to the field of exothermic chemical processing and energy harvesting. More specifically, the invention relates to an integrated chemical-to-electrical energy conversion system. The system comprises a modular reactor configured for the self-sustaining neutralization of waste streams and the concurrent generation of regulated power from internal exothermic thermal gradients.

### BACKGROUND

Current industrial processes for carbon capture and sustainable chemical synthesis are often hindered by extreme energetic demands and the rapid accumulation of waste byproducts. Traditional reactor designs are typically “energy-negative,” requiring more external power for thermal management and byproduct clearance than the environmental or commercial benefit they provide.

Furthermore, the lack of integrated energy harvesting within sequestration chambers leads to significant thermodynamic waste. There exists a critical need for a closed-loop reactor system that not only facilitates high-efficiency sustainable reactions, such as mineral carbonation, but also actively harvests the exothermic enthalpy of reaction (ΔH) to generate electrical power.

By integrating a high-efficiency thermal bus with energy-harvesting generators, the present invention addresses the need for a self-sustaining energy conversion environment. This allows the reactor to transition from an external power dependency during startup to a net-positive electrical output stream during the reactant conversion phase, thereby transforming methods such as carbon sequestration into a viable method of industrial power generation.

### BRIEF SUMMARY OF THE INVENTION

In one preferred embodiment, the present invention provides a method for introducing a mineral feedstock, such as forsterite (Mg₂SiO₄), a solvent such as water (H₂O), and a gaseous reactant such as carbon dioxide (CO₂) into a reactor assembly. The gaseous reactant may be isolated from industrial waste streams via PCC technology. The reactor converts the reactant CO₂ into thermal energy and mineralized byproducts, which may include materials suitable for biomineralization, such as magnesium carbonate (MgCO₃) and orthosilicic acid (Si(OH)₄). The process utilizes a ventral discharge chute to remove such byproducts, subsequently harvesting the enthalpy of reaction (ΔH) via a thermoelectric generator (TEG) array to cycle electrical energy back into the system for autonomous operation.

To address aforementioned deficiencies in existing green technologies, the present invention, hereinafter referred to as the “Thermoelectric Reactor,” is a multi-stage thermal-chemical interface. The device comprises parts such a central reaction center (“Core”), a radial thermal bus (“Copper Star”), and a dual-path nitrogen-based atmospheric control system.

It is an object of the invention to provide a method for converting exothermic reactions from industrial waste products into utility-grade electricity via the Seebeck effect. It is a further object of the invention to provide a batch processing cycle that ensures operation through a ventral discharge mechanism that occurs between each reaction cycle. By integrating a high-density thermoelectric array with a precision-engineered thermal manifold, the system achieves a steady-state energy export that significantly exceeds the parasitic power required for its internal control logic.

### BRIEF DESCRIPTION OF THE DRAWINGS

FIG. 1 is an overall cross-sectional view of the integrated multi-phase reactor system, illustrating elements such as the external housing [100], the external cooling shroud [104], and the primary input ports [138, 140, 142] and output [126] ports.

FIG. 2 is a cross-sectional view illustrating the thermal initiation and reactant entry phase (Stage 1), depicting the activation of the heat wire plurality [110] and the controlled entry of reactants [170, 172, 174] through the reactant pipes [138, 140, 142].

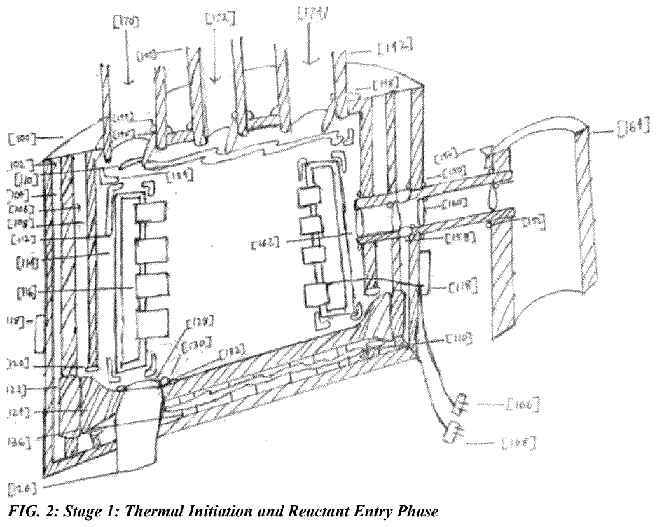

FIG. 3 is a cross-sectional view illustrating the active exothermic reaction phase (Stage 2), depicting the thermal flux from the innermost shell [108] through the thermal bus and into the TEG array [122], occurring simultaneously alongside release of the nitrogen cooling path [176] into the outermost space [102].

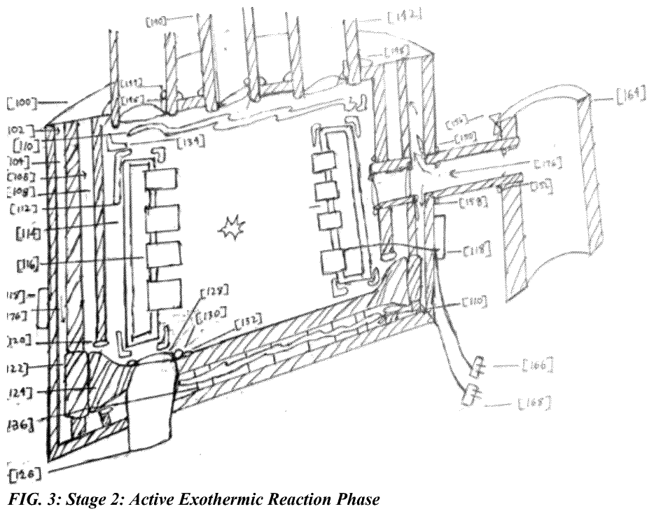

FIG. 4 is a cross-sectional view illustrating the byproduct clearance phase (Stage 3), depicting the activation of the synchronized nitrogen system clearing path, [190] clearing the innermost reactor space [180] and the gravity-assisted discharge through the ventral discharge chute [126].

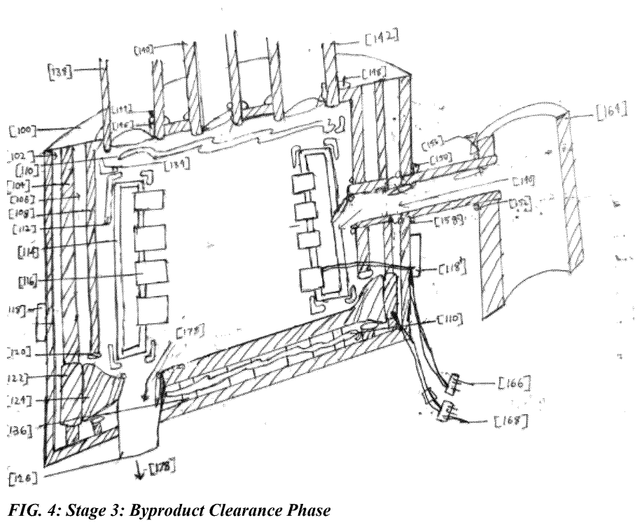

FIG. 5 is a top plan view of the reactor assembly [50], illustrating the radial symmetry of the copper star [124] and the concentric arrangement of the middle cooling shell and outermost shell [100].

FIG. 6 is a detailed, fragmentary view of the nitrogen reservoir [164] and the control center [118], illustrating the integrated electrical and pneumatic control interface. This view depicts the power output wire [168] originating from the DC converter [186], which is electrically coupled to the electrical export path [198] and the feedback path [202]. The control center [118] is shown interfacing with the electrical input wire [166], the communication paths [192, 194, 196], and the sensor array [116] to facilitate autonomous system regulation.

FIG. 7 is a top perspective view of the Copper Star [124] and side perspective view of one individual spoke, specifically illustrating the flared geometry of the radial spokes configured for maximized surface contact with the TEG array [122].

FIG. 8 is an exterior elevation view of the reactor assembly [50], illustrating the hermetically sealed outer housing and externally visible elements.

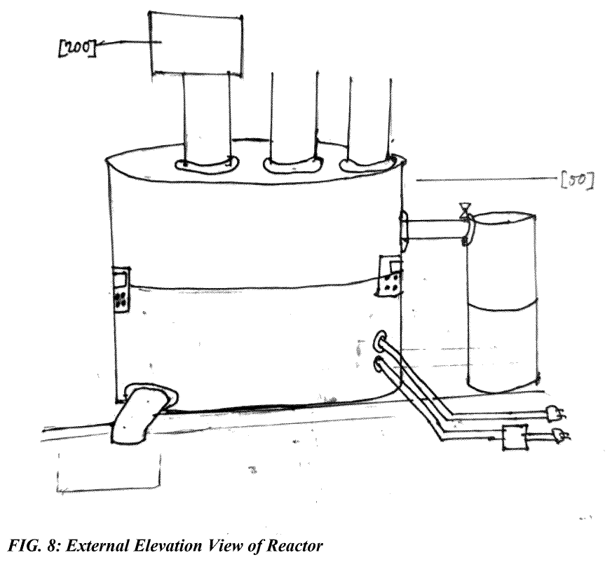

### DETAILED DESCRIPTION

### Section A: Legal & Conceptual Foundation

### Section 1: Definitions and Terminology

As used herein, the term “Batch Process” (or “Batch Operation”) refers to a discrete operational cycle characterized by the sequential introduction of reactants, a contained reaction period, and the subsequent evacuation of products. This is distinguished from a “continuous” or “semi-batch” process, in that the reaction chamber is to remain substantially sealed during the exothermic conversion phase, with no significant mass transfer across the system boundary until the reaction is complete.

The term “Reactant Feed” refers to any industrial byproduct, effluent, or mineral matter introduced into the reaction chamber for sequestration or neutralization. While one embodiment utilizes an aqueous waste stream (such as a dilute mineral acid), the reactant feed may also comprise gaseous, solid, or slurry-phase materials depending on the specific exothermic requirements of the core.

As used herein, the term “Thermal Bus” refers to a high-conductivity structural component configured to provide a preferential path for heat flux, specifically diverting thermal energy from a reaction zone to a conversion interface.

The term “Radial Star Geometry” refers to a structural arrangement comprising a central manifold and a plurality of elongate arms extending outwardly, configured to maximize surface-to-volume ratios for thermal dissipation.

### Section 2: General Overview

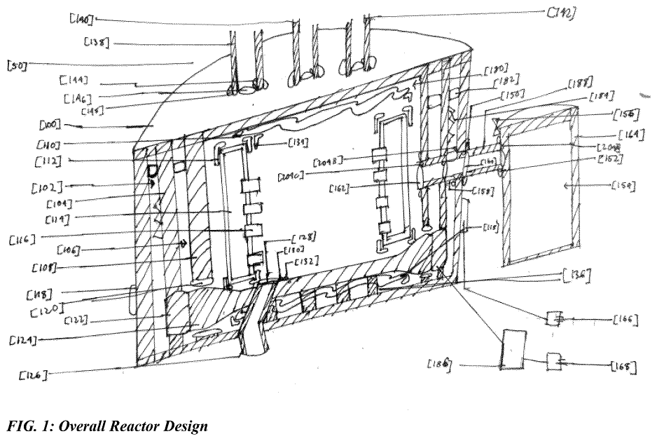

Turning now descriptively to the drawings, in which similar reference characters denote similar elements throughout the several views, FIG. 1 illustrates a schematic diagram of the modular, self-sustaining reactor assembly [50]. The reactor assembly integrates a high-enthalpy innermost shell [108] with a radial thermal bus [124] and a TEG array [122] to facilitate the simultaneous processing of industrial waste and the harvesting of exothermic energy.

The system features a centralized control center [118] that manages the dual-path nitrogen reservoir system [164], electrical input [166], Power Output [168] and the electrical paths [192, 194, 196, 198, 202] for startup, sensing, power export, and power recycling. By utilizing the enthalpy of reaction (ΔH) within the core [108], the reactor assembly [50] transitions from an externally powered startup phase to a self-sustaining operation mode. This architecture allows the reactor to transform reactant inputs such as CO₂ into a standardized electrical energy stream while discharging stabilized, high-purity mineral byproducts through the ventral discharge chute [126].

### Section B: The Physical Architecture

### Section 3: the Multi-Shell Reactor Design

The system comprises a Reaction Chamber [180], which serves as the primary reaction vessel. The Innermost shell [108] is constructed of a corrosion-resistant alloy capable of withstanding the thermal and chemical stresses of the reaction. The Reaction Chamber [180] provides the necessary volume for the continuous containment of an exothermic chemical transition.

The reactor assembly [50] comprises a nested shell architecture. The Innermost shell [108] defines the Reactor Chamber [180], which serves as the primary mineralization environment. This core is surrounded by Secondary spacing [106] and a Middle cooling shell [104], which is ultimately enclosed by Outermost Cooling spacing [102] and the Outermost shell [100]. This multi-layered spacing is maintained by a Plurality of spacers [182] situated within spaces [102] and [106], ensuring structural integrity and precise thermal insulation between the reaction environment and the exterior.

The reactor core [180] is hermetically isolated via a reactant pipe O-ring plurality [148], which is disposed circumferentially around the entire intake manifold. Within this sealed perimeter, a reactant pipe hinge plurality [144] and a reactant pipe hatch plurality [146] are operably coupled to primary input pipes [138, 140, 142]. This configuration ensures that the ingress of all mineral feedstock, catalysts, and aqueous solvents is controlled simultaneously, allowing the system to transition from a “Loading” state to a “High-Pressure Containment” state with a single synchronized actuation of the hatch plurality [146].

In a preferred embodiment, the reactor assembly [50] is configured to operate across a thermal spectrum, specifically optimized for an enthalpy of reaction (ΔH) ranging from −200 kJ/mol to −1200 kJ/mol. To accommodate higher energy densities within this range, the Thermal Bus [124] is constructed from a high-thermal-conductivity material (e.g., oxygen-free copper) to ensure rapid heat transfer away from the reaction core [108], thereby preventing thermal runaway during peak exothermic events.

### Section 4: Integrated Thermal Manifold

Disposed in direct thermal contact with the Innermost shell [108] is the Thermal Bus [124] (also referred to as the “Copper Star”). This high-conductivity thermal manifold is characterized by a radial star geometry designed for optimized heat flux distribution. The radial arms of the Thermal Bus [124] serve as the primary conduits for transferring exothermic energy from the reactor core [180] to the TEG plurality array [122].

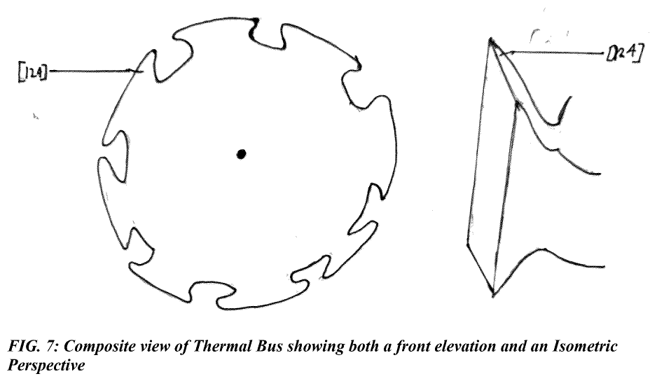

Extending outwardly from the central hub are a plurality of radial arms, collectively forming the “star” geometry of the Thermal Bus [124]. In the illustrated embodiment of FIG. 7, eight (8) symmetrical arms are utilized, though the number of arms may vary from four (4) to sixteen (16) depending on the required thermal load. Each arm is flared, having a wider terminus at the peripheral edge to maximize contact with the TEG array [122].

As illustrated in FIG. 1, the Thermal Bus [124] is primarily disposed within the internal volume of the Reactor Chamber [108]. To facilitate energy transfer, the radial arms (spokes) of the Thermal Bus [124] extend through the Chamber Wall [108], terminating at an interface in direct thermal contact with the peripheral energy-harvesting components [122]. This configuration allows the high-surface-area manifold to collect heat internally while providing a direct solid-state conduction path to the exterior [100] of the reaction vessel.

The Copper Star [124] is positioned in thermal communication with the Innermost shell [108]. To accommodate thermal fluctuations during exothermic carbonation, an Expansion seal for the copper star [124] is provided. The Thermal bus [124] transfers heat to the TEG array [122]. Power output wires [168] and Wires from the TEG array [198] connect to a DC converter [186].

The structural integrity of the nested architecture is maintained by a plurality of spacers [182] strategically positioned within the outermost cooling spacing [102] and the secondary spacing [106]. These spacers [182] ensure precise concentric alignment between the innermost shell [108] and the middle cooling shell [104], preventing mechanical shift during high-pressure cycles. Additionally, the heat wire plurality [110] is secured by a heat wire bracket plurality [134] and a bottom support [136] sustaining the thermal bus [124], providing vibration resistance and consistent thermal positioning relative to the reaction core.

At the distal end of each radial arm is a flattened interface flange configured for the mounting of the plurality of thermoelectric generators (TEGs) [122]. Each flange is polished to a surface roughness (Ra) of less than 0.8 micrometers to ensure planar contact with the ceramic face of the TEG unit plurality [122]. The flanges include integrated mounting apertures for non-thermal-conductive ceramic bolts, which secure the TEGs in a “sandwich” configuration between the manifold and the external cooling shroud. This arrangement ensures that the maximum temperature gradient ΔT is maintained across the TEG, maximizing the Seebeck effect efficiency.

Thermoelectric Generation Ratio. The Thermoelectric Generator (TEG) array [122] is configured in a predetermined 1:1 ratio with the radial spokes of the thermal bus [124]. Each TEG unit is dimensioned to substantially cover the entire surface area of its corresponding spoke, maximizing the thermal interface and ensuring uniform heat flux across the generating surface.

Electrical Busbar Retention. The busbars [114] are secured to the internal chassis via a plurality of brackets [112]. These brackets provide mechanical stability and maintain precise electrical spacing during high-vibration industrial scaling operations.

Thermal Expansion and Hermetic Sealing. A dynamic seal [120] is disposed at the interface of the thermal bus [124]. This seal is configured to accommodate the linear and radial thermal expansion of the copper manifold during exothermic spikes while simultaneously maintaining a hermetic seal for the cooling medium within the cooling channel [102].

Heat Wire Management. The heat wire plurality [110] is routed through a secondary bracket plurality [134]. This arrangement ensures that the wires remain isolated from the high-temperature core while maintaining a fixed orientation relative to the thermal bus [124].

In the preferred embodiment, the thermal bus [124] is machined from oxygen-free high-conductivity (OFHC) copper to ensure a thermal contact resistance of less than 5 K·m\hat{ }2/W at the interface where it meets the internal reaction environment. Furthermore, a thermal interface material (TIM), such as a graphite-based pad or silver-loaded paste, may be disposed between the hub and the core to eliminate air gaps and prevent localized thermal insulation.

### Section 5: Atmospheric and Fluid Control via Nitrogen Dual-Path System

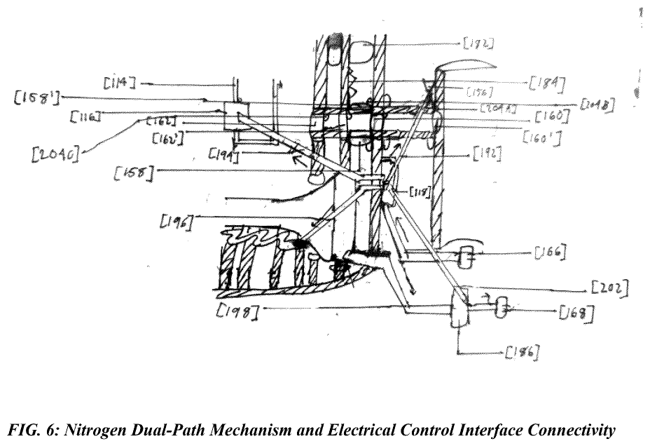

The cooling system is supplied by the nitrogen dual-path reservoir system [154], illustrated as a pressurized tank assembly. As represented in FIG. 6, A flow control switch [156] regulates the release of nitrogen from the reservoir [154] into the cooling channel [102] in a distinct gas pathway [176]. This ensures a consistent supply of cryogenic or ambient-temperature gas to maintain the cold-junction temperature of the thermoelectric generator (TEG) array [122].

To manage the reaction atmosphere, a nitrogen reservoir shell [164] contains the nitrogen gas reservoir [154], controlled by a flow control switch [156]. Nitrogen is routed through the Nitrogen pipe [188] containing reactor O-ring [150] and Nitrogen tank O-ring [152] via the nitrogen reservoir switch [156].

The nitrogen systems are electronically managed by a Control panel plurality [118] via Wires [192, 194, 196] to the Sensor array [116], nitrogen reservoir switch [156], and Heat wire plurality [110].

The nitrogen tank assembly [154] features a Synchronized cooling and release system configured for multi-stage operation.

First Primary Flowpath. Flowpath [176] defines Nitrogen Path 1, which is fluidly activated upon the concurrent actuation of Synchronized Hatch Duality 1 [160] and Synchronized Hatch Duality 2 [158]. This configuration facilitates the targeted delivery of nitrogen to the cooling channel [102] for thermal regulation of the nitrogen tank assembly [154].

Secondary Purge Flowpath. Flowpath [190] defines Nitrogen Path 2, activated via the synchronized opening of Synchronized Hatch Duality 1 [160] and Synchronized Hatch Duality 3 [162]. This flowpath is configured to clear the reactor core [180], propelling the byproduct stream [178] toward the discharge chute [126] for extraction.

Operational Stage 1: Thermal Initiation and Volumetric Loading. In Operational Stage 1, the control center [118] activates the heat wire plurality [110] to initiate a gradual thermal ramp within the reactor core [180]. Simultaneously, the reactant pipe hatch plurality [146] is actuated to introduce a predetermined volume of reactants. During this loading phase, the nitrogen dual-path system [164] remains in a ‘Static Ready’ state, with Synchronized Hatch Duality 1 [160], Synchronized Hatch Duality 2 [158], and Synchronized Hatch Duality 3 [162] substantially closed to prevent gas entry until the targeted ignition temperature is achieved. The ventral discharge chute [126] is maintained in a hermetically sealed position, ensuring the reaction volume is contained for the duration of the pre-heat cycle.

Operational Stage 2: Thermal Mitigation. During the active exothermic phase, the control center [118] initiates Nitrogen Path 1 [176] to maintain the temperature gradient (ΔT) across the TEG array [122]. This stage is characterized by the concurrent activation of Hinge Subset [204a] and Hinge Subset [204b], which actuates Synchronized Hatch Duality 1 [160] (the inlet) and Synchronized Hatch Duality 2 [158] (the cooling jacket entry). During this phase, Synchronized Hatch Duality 3 [162] remains hermetically sealed, ensuring that the nitrogen volume is directed exclusively into the outermost cooling spacing [102] to provide a constant cold-junction environment for energy harvesting without disturbing the internal reaction.

Operational Stage 3: Byproduct Extraction. To execute the clearing of the reactor core [180], the control center [118] initiates Nitrogen Path [190]. This sequence requires the concurrent activation of Hinge Subset [204a] and Hinge Subset [204c] to actuate Synchronized Hatch Duality 1 [160] (the inlet) and Synchronized Hatch Duality 3 [162] (the outlet). Upon activation, a high-pressure burst is routed from the nitrogen reservoir [164], creating a mechanical pressure differential that forcibly displaces the byproduct stream [178] through the ventral discharge chute [126].

All access hatches, or portals, associated with the nitrogen reservoir system [154] are operably coupled to a plurality of hinges [204a, 204b, 204c], and the nitrogen reservoir system [154] is managed by the nitrogen reservoir switch [156]. This allows the Control center [118] to execute precise, automated transitions between mineralization and clearing phases. Each hinge subset is independently addressable by the control center [118]. This allows for the precise, staggered actuation required to transition between the inert blanketing of Stage 2 and the pressurized scavenging of Stage 3.

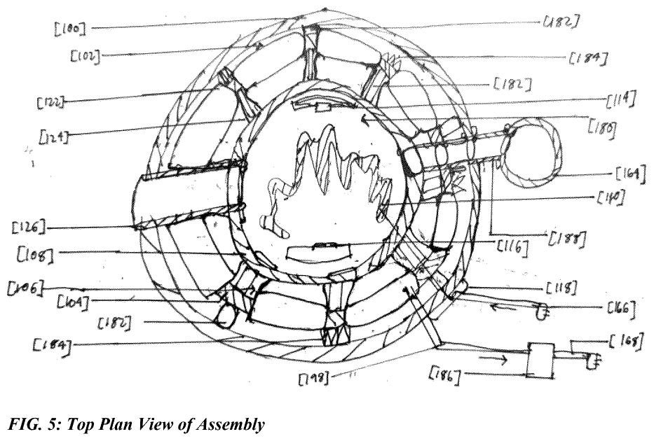

Referring to FIG. 5, the atmospheric control system comprises a primary nitrogen reservoir [154] connected to the reactor core via a dual-path manifold. Nitrogen Path 1 [176] is configured to maintain a continuous inert “blanket” within the core at a pressure of approximately 1.1 to 1.5 atm, effectively displacing oxygen to prevent unwanted oxidation of the reactants. Nitrogen Path 2 [190] is a high-pressure “scavenging” line. Upon a trigger signal from the control logic, the second path delivers a concentrated burst of nitrogen to the upper manifold, creating a pressure differential that forcibly ejects the aqueous product through the ventral discharge chute. This dual functionality ensures that the same gas supply provides both chemical stabilization and mechanical transport.

The nitrogen pipe [188] attached to the nitrogen reservoir shell [164] is hermitically sealed with O-Rings [150, 152].

### Section 6: Thermal Management and Cooling Shroud

The External Cooling Assembly. The external cooling assembly, or shroud [104], serves as the low-temperature reservoir for the thermoelectric conversion process. The shroud [104] is configured to circumferentially encompass the radial thermal manifold, creating a sealed thermal gradient across the intervening thermoelectric generators (TEGs) [122]. In the preferred embodiment, the shroud is constructed from a lightweight, high-surface-area material such as 6061-T6 aluminum. The interior surface of the shroud features localized mounting pedestals, which are precision-aligned with the interface flanges of the copper star arms described in Section 4.

Attached to the exterior surface of the secondary shell [104] is a cooling fin plurality [184]. These fins are designed to increase the total surface area in contact with the external environment, facilitating rapid convective heat dissipation and preventing thermal saturation of the internal TEG array [122]. This external configuration allows the inside of reactor core [180] to maintain the high-enthalpy conditions necessary for mineralization while ensuring the exterior skin of the secondary shell [104] remains within safe operational limits.

To maintain the necessary temperature differential ΔT, the exterior surface of the cooling shroud [104] is populated with a plurality of longitudinal heat dissipation fins [184]. These fins increase the effective surface area of the device by at least 400%, allowing for convective cooling via ambient air. The fin geometry is optimized for “natural stack effect” airflow, wherein rising heat draws cooler air upward through the device housing. In alternative embodiments, the fins may be shrouded in a fan-driven ducting system for forced-air cooling in high-load industrial environments.

In a secondary embodiment, specifically for high-density “factory treadmill” configurations, the cooling shroud [104] may further comprise an internal liquid-cooling jacket. This jacket includes a helical flow path configured to circulate a coolant, such as a glycol-water mixture or a dielectric oil, in close proximity to the cold-side faces of the TEGs. This embodiment allows the device to operate at significantly higher molar throughputs by removing heat at a rate exceeding 500 W per radial arm, thereby preventing thermal saturation of the copper thermal bus [124].

### Section C: Energy and Flow

### Section 7: Thermoelectric TEG Conversion and Logic

The thermoelectric array comprises a plurality of bismuth-telluride (Bi₂Te₃) modules [122] positioned in a high-density grid. Each module is “potted” in a thermally conductive epoxy to protect the semiconductor junctions from vibration.

Before the energy is exported, it passes through a DC-to-DC buck-boost converter [186] to stabilize the voltage. This ensures that the fluctuating heat of a semi-batch reaction results in a “clean” voltage output. Energy that is recycled follows a path back into the reactor [202].

### Section 8: Waste Management

For the controlled evacuation of processed materials, the assembly [50] comprises a ventral discharge chute [126] disposed at the inferior terminus of the reactor core [180]. The discharge chute [126] further comprises a sealing hatch [128], a mechanical hinge [130], and a hermetic O-ring [132] configured to maintain pressure integrity during the mineralization phase.

Gravity-Assisted Isolation. This gravity-fed conduit ensures that waste byproducts are environmentally isolated from the electrical control interface [118] and the TEG array [122]. The ventral orientation of the chute [126] utilizes gravitational force in conjunction with the Nitrogen Path 2 [190] scavenging pressure to facilitate the total clearance of the core between batch cycles, effectively preventing the accumulation of mineralized residue on the innermost shell [108].

### Section 9: Startup and Electrical Flow

System Initiation and Control. The control center [118] serves as the primary logic and power distribution hub for the reactor assembly [50]. To initiate the chemical process, the control center [118] energizes an auxiliary resistive ignition heat wire plurality [110] configured to deliver localized activation energy. Upon the detection of a self-sustaining exothermic threshold by the sensor array [116], the control center [118] is configured to automatically decommission the ignition sequence and transition to an energy-harvesting mode.

Integrated Actuation Control. The control center [118] is communicatively and electrically coupled to every actuated component within the reactor assembly [50], including but not limited to the reactant pipe hinge plurality [144] and the nitrogen pipe hatch dualities [158, 160, 162]. The control center [118] comprises logic to synchronize the mechanical state of these components with the operational stages defined herein, ensuring hermetic containment or pressurized discharge as required by the system telemetry.

The system comprises a plurality of hinges [204a, 204b, 204c], wherein each subset of hinges is independently addressable by the control center [118] to facilitate the synchronized timing of the nitrogen flowpaths.

The mechanical actuation of the nitrogen system is bifurcated into specific functional subsets to facilitate independent flow control. Specifically, the first hinge subset [204a] is operably coupled to synchronized hatch duality 1 [160]; the second hinge subset [204b] is operably coupled to synchronized hatch duality 2 [158]; and the third hinge subset [204c] is operably coupled to synchronized hatch duality 3 [162]. This mapping allows the control center [118] to execute the distinct Nitrogen Path 1 [176] and Nitrogen Path 2 [190] sequences by selectively energizing only the required hinge subsets for each operational stage.

Activation and Thermal Ignition. During the startup phase, the control center [118] is energized via an external power source to manage the auxiliary resistive ignition system. The heat wire plurality [110] provides the specific enthalpy required to catalyze the mineralization reaction within the innermost shell [108]. Once the sensor array [116] confirms that the core temperature and reaction rate have reached a predetermined exothermic equilibrium, the control center [118] deactivates the external power input to maximize net system efficiency.

Electrical Command and Control Architecture. The system architecture defines specific electrical pathways for synchronized operation. An electrical input wire [166] provides initial power to the control center [118]. Electrical path 1 [196] facilitates the transmission of ignition current from the control center [118] to the heat wire plurality [110]. Electrical path 2 [194] facilitates the transmission of real-time telemetry from the sensor array [116] to the control center [118]. Additionally, electrical path 3 [192] facilitates communication between the control center [118] and the flow control switch [156] to coordinate atmospheric purging sequences during the ignition cycle.

Power Generation and Feedback Loops. Following ignition, the TEG array [122] generates electrical current derived from the thermal flux of the thermal bus [124]. An electrical export path [198] routes this generated power to the DC converter [186] for voltage regulation. To facilitate autonomous operation, a feedback path [202] routes a portion of the regulated power from the DC converter [186] back to the control center [118]. Any residual surplus power is directed from the DC converter [186] to the power output wire [168], serving as the primary output stream for external utility or storage applications.

### Section D: The Process and Results

### Section 10: Method of Operation Stages

Operational Overview. The operation of the reactor assembly [50] is characterized by three distinct operational phases designed to transition the system from external dependency to self-sustained mineralization and power generation.

Stage 1: Thermal Initiation and Priming. During the startup phase, the control center [118] directs external power to the heat wire plurality [110]. Concurrently, a controlled stream of reactants [170, 172, 174] is introduced via the respective reactant pipes [138, 140, 142] as the reactant hatch plurality [146] is actuated to an open position. This concurrent loading allows the mineral feedstock to reach thermal equilibrium with the innermost shell [108] prior to the initiation of the primary sequestration reaction.

Atmospheric Stabilization. While Stage 1 typically maintains the nitrogen system in a closed state, the system may selectively activate Nitrogen Path 2 [190] via the opening of hatch duality 1 [160] and hatch duality 3 [162]. The flow control switch [156] provides a low-flow purge via flowpath [190] to the reactor core [180] to stabilize internal atmospheric pressure of no more than 1.1 atm and displace ambient oxygen.

Stage 2: Exothermic Transition and Harvesting. Upon reaching the specific activation enthalpy, the exothermic mineralization reaction commences within the reactor core [180]. The resulting thermal energy is harvested by the thermal bus [124], initiating a thermal flux toward the TEG array [122]. The TEG array converts this flux into DC electrical energy, which is regulated by the DC converter [186].

Energetic Autonomy. Regulated power is internally routed via the feedback path [202] to satisfy the energetic requirements of the sensor array [116], the nitrogen reservoir control [156], and the onboard control logic, rendering the nitrogen assembly [154] energetically autonomous. During Stage 2, Nitrogen Path 1 [176] is activated via the opening of hatch duality 1 [160] and hatch duality 2 [158] to maintain the necessary thermal gradient for optimized thermoelectric conversion.

Stage 3: Stabilization and Product Discharge. In the final phase, surplus electrical energy is routed through the power output wire [198]. Simultaneously, the flow control switch [156] actuates Nitrogen Path 2 [190] via the opening of hatch duality 1 [160] and hatch duality 3 [162]. Nitrogen travels through the reactor core [180] to displace mineralized byproducts through the discharge chute [126] along the byproduct outflow stream [178]. This clearing stage resets the innermost shell [108] for the subsequent reaction cycle.

Universal Feedstock Configuration. The assembly facilitates precisely controlled mineralization via three primary input lines: reactant pipe 1 [138], reactant pipe 2 [140], and reactant pipe 3 [142]. These pipes define the flowpaths [170, 172, 174] for inflow streams; notably, these flowpaths are defined functionally and are not limited to specific chemical reactants. Each inflow line is secured by a reactant pipe hinge plurality [144], hatch plurality [146], and O-ring plurality [148] to maintain a pressurized, hermetic environment.

Batch Process Logic. The device operates as a cyclical batch process, wherein reactants are introduced at controlled intervals to maintain an exothermic steady-state, while byproducts are discharged via the ventral chute [126] to prevent thermal dampening and accumulation.

### Section 11: Operational Parameters and Stochiometry Ratios

The system is configured to maintain a precise chemical balance. In the preferred embodiment, the input reactants [138, 140, 142] are introduced in a stoichiometric ratio designed to target an enthalpy of reaction (ΔH) range of approximately −200 kJ/mol to −1200 kJ/mol. For example, a ratio of 2:1:1 may be utilized depending on the molar concentration of the aqueous waste stream to ensure the reaction remains in a self-sustaining exothermic state without reaching thermal runaway.

To ensure efficient energy harvesting, the ratio of the internal surface area of the Reactor Core to the contact surface area of the Thermal Bus [124] is maintained between 1:1.5 and 1:3. This “Oversized Contact” allows the copper to act as a thermal sponge, rapidly drawing heat away from the core to protect the structural integrity of the thermal bus [124] while maximizing the ΔT (temperature difference) across each TEG comprising the array [122].

The process is characterized as a batch process, meaning that the inflow of reactants is not continuous during Stage 3, the discharge via the Ventral Chute is regulated by the Nitrogen Dual System. This maintains a specific “Liquid Level” or “Molar Density” within the core, ensuring the heat wire plurality [110] is always in contact with enough material to maintain the “spark” of the reaction.

The mass of the Thermal Bus [124] is specifically dimensioned relative to the peak molar output. The ratio of Copper Mass (kg) to Molar Throughput (mol/second) is optimized to provide enough “Thermal Inertia” so that minor fluctuations do not cause the TEGs to lose voltage.

### Section 12: Working Examples

### Example 1: Exothermic Carbon Sequestration

In a preferred embodiment, the reactor assembly [50] is configured to repurpose carbon dioxide (CO₂) generated as an industrial waste product. Post-combustion capture (PCC) technology [200] facilitates the regulated inflow of CO₂ into the reactant pipe [138].

Reaction Chamber Architecture. The system comprises specialized entryways for the initial injection of energy and reactants into the primary reaction core. This core facilitates the aqueous mineralization of olivine Mg₂SiO₄, CO₂, and water (H₂O). The assembly further includes an advanced filtration unit for the continuous removal of magnesium carbonate (MgCO₃) and orthosilicic acid Si(OH)₄. A dedicated byproduct collection chamber is provided for these materials, isolated by the thermal bus [124]—a copper barrier serving as the primary conductor for harvesting exothermic heat energy.

Catalytic Efficiency. In the primary reactor, the Mg₂SiO₄ is processed in the presence of a catalyst, such as nickel ions (Ni²⁺), to enhance the conversion efficiency of CO₂ into stabilized MgCO₃ and Si(OH)₄.

Byproduct Commercialization. The resultant MgCO₃ and Si(OH)₄ are sequestered in a separate compartment and are suitable for use as biomineralization materials, construction aggregates, or other commercially viable industrial products following removal from the reactor assembly [50].

Self-Sustaining Energy Cycle. The reactor is configured to sustain its operational state primarily via the heat energy released during the exothermic CO₂ conversion process, significantly increasing the net energy efficiency of the sequestration procedure. The balanced chemical reaction is represented as follows:

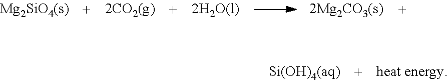

### Example 2: Processing of a Dilute Acidic Industrial Waste Stream.

In a second operational example, the device is to be configured to process an aqueous waste stream comprising 15% sulfuric acid (H₂SO₄). The reactor core is to be pre-heated via the Startup System [118] to an ignition temperature of 80° C. Upon reaching the target temperature, Reactant A (a neutralizing base) and Reactant B (a stabilizing catalyst) are to be introduced via the input ports [138, 140, 142] at a flow rate of 0.5 L/min.

Within 120 seconds of injection, the internal temperature of the reactor core [180] shall rise to a steady-state value of 220° C., indicating the onset of the targeted −200 kJ/mol exothermic reaction. The Thermal Bus [124] is to divert the resultant heat flux toward the TEG array [122]. During this phase, the Nitrogen Dual-Path System shall maintain an internal pressure of 1.2 atm, preventing any oxidative degradation of the internal manifold coatings.

The temperature differential (ΔT) between the Copper Star [124] arms and the External Cooling Shroud [104] shall be measured at 140° C. This gradient shall produce a continuous electrical output of 120 Watts across the TEG array. Of this power, 15 Watts shall be diverted to maintain the control logic and sensor array, while the remaining 105 Watts shall be exported to the external utility bus [168]. The process is to continue for a duration of 4 hours before a “purge” is to be triggered to remove the resultant salts and refresh the reaction environment.

### Example 3: Processing of High-Enthalpy Organic Solvent Byproducts.

In a third operational example, the device shall be utilized to process a waste stream of concentrated nitrated organics, which possess a higher energy density than the stream in Example 1. Due to the rapid kinetic nature of this reaction, the stoichiometric ratio was adjusted to 3:1 (Reactant C to Waste) to act as a thermal buffer.

During the peak of the exothermic phase, internal core pressure shall rise to approximately 4.5 atm. The control logic [118] shall detect the pressure spike and automatically modulate the Nitrogen Dual-Path system [154] to increase the “blanket” pressure, preventing the formation of volatile vapor pockets. The radial arms of the Copper Star [124] shall successfully maintain the core wall [108] temperature below the critical failure threshold of the internal coatings (500° C.).

To demonstrate the safety “fail-safe” of the batch process, a manual emergency stop shall be triggered. The system shall initiate Nitrogen Path 2 [190], clearing the reaction zone in under 5 seconds and returning the device to a safe, inert state. This example demonstrates the device's ability to maintain structural and operational integrity even under volatile chemical conditions.

### Example 4: Processing of High-Solids Mining Tailings.

In a fourth operational example, the device shall utilize a mineral slurry containing 25% suspended solids by volume. Unlike the liquid-phase waste in Examples 1 and 2, this “heavy slurry” presents a significant risk of sedimentation and thermal insulating “crust” formation on the interior walls of the reactor core.

To accommodate the heavy particulate matter, the device shall be oriented in a vertical “ventral-down” configuration. The reactants shall be injected via a high-velocity “cyclonic” nozzle in input ports [138, 140, 142], creating a vortex that kept the solids in suspension during the exothermic phase. This shall ensure that the heat generated by the reaction remains in direct contact with the interior wall of the Reactor Core, allowing the Thermal Bus [124] to maintain its cooling efficiency.

Upon completion of the reaction cycle, the Nitrogen Dual-Path System [154] shall be engaged at a burst pressure of 8.0 atm. This high-pressure pulse, combined with the gravitational pull of the ventral discharge chute, is to eject the mineralized “spent” slurry without leaving significant residue. Post-operational inspection shall be implemented to reveal that the internal coatings remained intact, and no “bridging” (clogging) occurred within the discharge chute [126]. This example demonstrates the device's utility in “rugged” industrial environments where waste streams are non-homogeneous.

### Section E: Maintenance and Scaling

### Section 13: Modular Array and Industrial Scaling

In a primary industrial embodiment, a plurality of reactor assemblies [50] is arranged in a linear or grid-based “treadmill” configuration to facilitate high-volume waste processing. This modular approach allows for the continuous operation of the facility; while a first subset of reactors is in Stage 1, a second subset is in Stage 2, and a third subset is undergoing Stage 3. By staggering the operational phases of the individual units, the total electrical output of the array is smoothed, providing a constant, non-oscillating power feed to a local micro-grid.

To reduce mechanical complexity, the modular array is serviced by a unified reactant delivery system. In this embodiment, a master reservoir of reactants is coupled to a high-pressure common-rail manifold. This manifold utilizes individual solenoid-actuated valves for each reactor unit, allowing the control center [118] to “pulse” reactants into specific cores based on real-time enthalpy demands. Similarly, a master nitrogen reservoir [154] provides the stabilization and purge gas for the entire array.

Each reactor in the treadmill array is electrically coupled in a series-parallel configuration to a centralized power conditioning hub. By utilizing a “Summation Logic,” the system can compensate for a localized failure in a single reactor unit by modulating the throughput of adjacent units. This ensures that the facility maintains a “High Availability” status.

A key advantage of the modular configuration is the ability for “hot-swap” maintenance. Each flange of the thermal bus [124] is mounted via a quick-disconnect system. This allows an individual reactor core [180] or thermal manifold [124] to be removed and replaced without halting the operation of the remaining units in the array.

### Section 14: Maintenance and Safety Protocols

Due to the high-mineral content of the aqueous waste streams, the interior of the reactor core [180] is subject to the accumulation of scale and mineral crust. To maintain optimal thermal conductivity between the reaction zone and the conductive thermal bus [124], the system is programmed for a “Maintenance Rinse” cycle. During this rinse, a mild chelating agent is introduced through the inflow ports [138, 140, 142] and agitated via the cyclonic nozzle. The resultant effluent is then discharged through the ventral chute [126], ensuring that the heat transfer efficiency of the core wall remains within 95% of its factory-calibrated baseline.

The control center [118] utilizes a triple-redundant sensor architecture. Each “arm” of the thermal bus [124] contains an embedded thermocouple, and the core itself contains two independent pressure transducers. The logic employs a “voting” algorithm; if one sensor [116] provides a reading that deviates by more than 15% from the average of its peers, the system flags the sensor for replacement while continuing to operate on the remaining two data points. This prevents an unnecessary emergency shutdown during critical exothermic phases.

The external cooling shroud [104] serves a secondary function as a tertiary containment vessel. In the event of a structural breach of the innermost shell [108], the shroud is hermetically sealed to prevent the escape of reactants or gases. A dedicated pH sensor located in the lower sump of the shroud is configured to detect the presence of acidic waste. Upon detection of a leak, the nitrogen dual-path system [164] is immediately locked into nitrogen Path 1 [176] constant-pressure mode to inert the environment.

The modular design of the thermal bus [124] allows for the servicing of the TEG array [122] without disassembling the primary chemical manifold. By removing the exterior finned panels of the cooling shroud [104], the TEG array [122] can be accessed. Because the

TEGs are secured in a compression-fit “sandwich” configuration using ceramic-coated bolts, a technician can replace a degraded module by loosening the tensioning hardware, sliding out the old module, and inserting a new unit with fresh thermal interface material (TIM).

1. A chemical reactor assembly for the processing of industrial waste, comprising:
a plurality of reactant pipes [138, 140, 142] configured to deliver reactants to a reaction volume [180];
an innermost shell [108] defining a reaction core configured to facilitate an exothermic reaction;
a thermal bus [124] in direct thermal contact with said innermost shell [108] configured to capture and distribute thermal energy; and
a TEG array [122] in thermal communication with said thermal bus [124] configured to convert said thermal energy into electrical energy.

2. The chemical reactor of claim 1, wherein the thermal bus [124] comprises a central hub and a plurality of radial arms extending outward toward the TEG array [122].

3. The chemical reactor of claim 1, further comprising an atmospheric control system comprising a nitrogen reservoir tank [164] and a dual-path nitrogen system [154] configured to deliver nitrogen gas for stabilization and pressurized discharge.

4. The chemical reactor of claim 3, wherein the nitrogen atmospheric control system is configured to maintain an internal core pressure between 1.1 and 1.5 atm for the duration of the present chemical reaction.

5. The chemical reactor of claim 1, wherein the innermost shell [108] comprises a pill-shaped geometry having a curved interior surface configured to facilitate cyclonic fluid mixing.

6. The chemical reactor of claim 2, wherein the plurality of radial arms of the thermal bus [124] are divergent, having a surface area that increases as the arms extend away from the central hub to provide a maximized mounting interface for the TEG array [122].

7. The chemical reactor of claim 1, further comprising a ventral discharge chute [126] positioned at a gravitational low point of the reactor core for the intermittent removal of byproducts.

8. The chemical reactor of claim 1, wherein the reactants are introduced in a stoichiometric ratio configured to target a specific enthalpy of reaction (ΔH) of approximately −200 to −1200 kJ/mol.

9. The chemical reactor of claim 1, wherein the TEG array [122] is electrically coupled to a DC converter [186] configured to stabilize electrical output.

10. The chemical reactor of claim 1, wherein the sensor array [116] is in thermal communication with the plurality of busbars [114] to modulate reactant flow rates in response to real-time thermal data.

11. The chemical reactor of claim 1, further comprising an internal protective coating on the innermost shell [108] selected from the group consisting of: technical ceramics, fluorinated polymers, and borosilicate glass.

12. The chemical reactor of claim 1, wherein the thermal bus [124] is secured to the innermost shell [108] via a thermal interface material (TIM) having a thermal conductivity of at least 5 W/m·K.

13. The chemical reactor of claim 1, further comprising a cooling shell [104] featuring a cooling fin plurality [184] configured to facilitate passive convective heat transfer.

14. A modular reactor system comprising a plurality of the chemical reactors of claim 1 arranged in a staggered operational array.

15. The modular reactor system of claim 14, further comprising a common-rail reactant manifold configured to deliver pressurized reactants to each of the plurality of reactors via independently controlled solenoid valves.

16. The modular reactor system of claim 14, further comprising a unified power bus configured to aggregate electrical output into a single high-voltage DC output.

17. The chemical reactor of claim 3, further comprising a fail-safe logic configured to trigger a high-pressure nitrogen purge if a temperature threshold is exceeded.

18. The chemical reactor of claim 1, wherein the reactant pipes comprise a cyclonic injection nozzle configured to induce a vortex flow.

19. The chemical reactor of claim 1, wherein the electrical energy generated by the TEG array [122] renders the assembly energy-autonomous during steady-state operation.

20. A method for harvesting energy from industrial waste processing using the assembly of claim 1, comprising the steps of:
(a) introducing reactants into the reaction volume [180];
(b) facilitating an exothermic reaction within the innermost shell [108] to produce a thermal flux;
(c) conducting said thermal flux through a radial thermal bus [124] to a TEG array [122]; and
(d) converting said thermal flux into electrical energy via the Seebeck effect.
